(19) United States
(12) Patent Application Publication
(10) Pub. No.: US 2026/0052708 A1
(43) Pub. Date: Feb. 19, 2026

(54) SEMICONDUCTOR PACKAGE HAVING BIFACIAL SEMICONDUCTOR WAFERS

(71) Applicant: Sandisk Technologies, Inc., Milpitas, CA (US)

(72) Inventors: Lei Shi, Shanghai (CN); Weiting Jiang, Shanghai (CN); Cong Zhang, Shanghai (CN); Chien Te Chen, Taichung (TW); Chiang Chung Yu, Taichung (TW); Ching Wei Hsu, Taichung (TW); Yangming Liu, Shanghai (CN); Chaolun Zheng, San Jose, CA (US); Ye Bai, Shanghai (CN); Nirbhaya Pathak, Penang (MY)

(21) Appl. No.: 18/803,091

(22) Filed: Aug. 13, 2024

(51) Int. Cl. H10B 80/00; H01L 23/00; H01L 23/13; H01L 23/48; H01L 23/498; H01L 23/538; H01L 25/18; H10B 41/20; H10B 41/40; H10B 43/20; H10B 43/40

(52) U.S. Cl. CPC H10B 80/00; H01L 23/481; H01L 23/49816; H01L 25/18; H10B 41/20; H10B 41/40; H10B 43/20; H10B 43/40; H01L 23/13; H01L 23/5386; H01L 24/08; H01L 24/16; H01L 24/24; H01L 24/32; H01L 24/73; H01L 24/94; H01L 2224/08146; H01L 2224/16145; H01L 2224/16227; H01L 2224/24137; H01L 2224/32145; H01L 2224/32225; H01L 2224/73204; H01L 2224/94; H01L 2924/1431; H01L 2924/1438

(57) ABSTRACT

A semiconductor package having one or more bifacial NAND memory devices includes an interposer including a plurality of multiplexers (MUX) integrally formed within the interposer, and a plurality of bifacial NAND memory devices disposed over the interposer. The bifacial NAND memory devices are electrically coupled to the MUX. Each bifacial NAND memory device includes a first NAND memory die disposed on a first planar surface, and a second NAND memory die disposed on a second planar surface, opposite the first NAND memory die, and adjacent the interposer. Each bifacial NAND memory device also includes a plurality of through silicon vias (TSVs) electrically coupling the first NAND memory die with the second NAND memory die, and the MUX.

### BACKGROUND

In a traditional high-capacity memory device, such as, for example, a three-dimensional (3D) NAND memory device, semiconductor dies are vertically stacked on top of one another. In order to facilitate communication between different semiconductor dies, edges of the stacked semiconductor dies are often offset from one another. A bond wire is used to connect a bond pad of one semiconductor die in the stack of semiconductor dies to a bond pad of another semiconductor die in the stack.

In order to increase the storage capacity of a high-capacity memory device, additional semiconductor dies may be added to the stack. However, current high-capacity memory devices are limited in the number of semiconductor dies that can be included in the stack. For example, as additional semiconductor dies are added, the overall size of the high-capacity memory device increases and consumes more space, wire bonding becomes more difficult, and the semiconductor die may be subject to warpage, die tilt or other manufacturing issues.

Accordingly, it would be advantageous to increase the storage capacity of a memory device while maintaining or reducing the size of the memory device and avoiding the other manufacturing issues outlined above.

### SUMMARY

The present application describes a semiconductor package that includes a number of vertically stacked bifacial NAND memory devices. For example, a first surface, or face, of each bifacial NAND memory device includes a first circuit layer. Additionally, a second surface, or face, of each bifacial NAND memory device includes a second circuit layer. In an example, the first circuit layer and the second circuit layer may include NAND memory dies and/or storage/signal transmission circuitry.

The bifacial NAND memory device of the present disclosure is described as having a first circuit layer on a first surface and a second circuit layer on a second surface. It should be understood that the first circuit layer and its associated second circuit layer comprise a bifacial semiconductor die. Further, it should be understood that the bifacial NAND memory device described herein may consist of a series of bifacial NAND memory dies.

The semiconductor package can include a plurality of bifacial NAND memory devices disposed over, positioned on and/or electrically coupled to an interposer as well. That is, the semiconductor package can include an interposer positioned below, directly in contact with at least one bifacial NAND memory device, and/or supporting the bifacial NAND memory device forming the semiconductor package. In an example, a plurality of multiplexers (MUX) may be formed integrally within the interposer. As such, each of the plurality of bifacial NAND memory devices included in the semiconductor package may be electrically coupled to the plurality of MUX integrally formed within the interposer as well as being electrically coupled to one another.

Accordingly, the present application describes a semiconductor package including an interposer including a plurality of multiplexers (MUX) integrally formed within the interposer, and a plurality of bifacial NAND memory devices disposed over the interposer. In the example the plurality of bifacial NAND memory devices are electrically coupled to the MUX integrally formed within the interposer. Each bifacial NAND memory device includes a first NAND memory die disposed on a first planar surface, and a second NAND memory die disposed on a second planar surface, opposite the first NAND memory die, and adjacent the interposer. Each bifacial NAND memory device also includes a plurality of through silicon vias (TSV) electrically coupling the first NAND memory die with the second NAND memory die, and the MUX integrally formed within the interposer.

Also described is an electronic device that includes a printed circuit board (PCB), and at least one semiconductor package positioned on and electrically coupled to the PCB. In an example, the at least one semiconductor package includes an interposer disposed directly over and electrically coupled to the PCB. The interposer includes a plurality of multiplexers (MUX) integrally formed within the interposer. The at least one semiconductor package also includes a plurality of bifacial NAND memory devices disposed over the interposer and electrically coupled to the plurality of MUX integrally formed within the interposer and the PCB. In the example, each of the plurality of bifacial NAND memory devices includes a first NAND memory die disposed on a first planar surface, and a second NAND memory die disposed on a second planar surface, opposite the first NAND memory die. The second planar surface is positioned adjacent the interposer. Additionally in the example, each of the plurality of bifacial NAND memory devices includes a plurality of through silicon vias electrically coupling the first NAND memory die on the first planar surface with the second NAND memory die on the second planar surface, and the plurality of MUX integrally formed within the interposer.

Additionally, the present application also describes a semiconductor package. The semiconductor package includes an interposer including a plurality of multiplexers (MUX) integrally formed within the interposer and a plurality of bifacial NAND memory devices disposed over the interposer. Each of the plurality of bifacial NAND memory devices includes a first NAND memory die disposed on a first planar surface, a second NAND memory die disposed on a second planar surface, opposite the first NAND memory die. The second planar surface is positioned adjacent the interposer. Each of the plurality of bifacial NAND memory devices also includes means for electrically coupling the first NAND memory die on the first planar surface with the second NAND memory die on the second planar surface, and the plurality of MUX integrally formed within the interposer.

The present application also describes a method for fabricating a semiconductor package. In an example, the method includes disposing a first bifacial NAND memory device directly over an interposer. The interposer includes a plurality of multiplexers (MUX) integrally formed therein. In the example, the method also includes electrically coupling the first bifacial NAND memory device to the plurality of MUX integrally formed within the interposer and positioning at least one distinct bifacial NAND memory device over the first bifacial NAND memory device.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates a bifacial NAND memory device including NAND memory dies on opposing planar surfaces according to an example.

FIG. 1B illustrates a cross-sectional view of the bifacial NAND memory device shown in FIG. 1A taken along line 1B-1B, according to an example.

FIG. 2 illustrates an interposer including a plurality of multiplexers (MUX) integrally formed within the interposer according to an example.

FIG. 3A illustrates a semiconductor package including a plurality of bifacial NAND memory devices disposed over an interposer according to an example.

FIG. 3B illustrates a cross-sectional view of the semiconductor package of FIG. 3A according to an example.

FIG. 4 illustrates a cross-sectional view of a semiconductor package including a plurality of bifacial NAND memory devices disposed over an interposer according to another example.

FIGS. 5A-5C illustrate a cross-sectional view of a semiconductor package including a plurality of bifacial NAND memory devices disposed over an interposer, and a controller according to an example.

FIG. 6 illustrates a bifacial NAND memory device including a first NAND memory device portion and a second NAND memory device portion according to an example.

FIG. 7 illustrates an electronic device including a printed circuit board (PCB) and a plurality of semiconductor packages each including a plurality of bifacial NAND memory devices according to an example.

FIG. 8 illustrates a method for fabricating a semiconductor package including bifacial NAND memory devices according to an example.

FIG. 9 illustrates a method for fabricating a semiconductor package including bifacial NAND memory devices according to another example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

In traditional three-dimensional (3D) NAND memory devices, a semiconductor wafer having an array of memory cells is vertically stacked on another semiconductor wafer having another array of memory cells. As the number of layers increases, the storage capacity of the memory device increases.

However, current 3D NAND memory devices are limited in the number of layers that can be stacked together. For example, as additional semiconductor wafers are added to the 3D NAND memory device, the overall size of the 3D NAND memory device increases. Additionally, as additional layers are added, manufacturing becomes more complex and costly (in terms of time and/or materials). Adding additional semiconductor wafers can also increase an amount of stress that is induced on the semiconductor wafers which can subsequently warp the semiconductor wafers. Warped semiconductor wafers can negatively impact the performance of the 3D NAND memory device.

In order to address the above, the present disclosure describes semiconductor packages including a plurality of bifacial NAND memory devices for use in 3D NAND memory devices. Although 3D NAND memory devices are specifically mentioned, the examples described herein may be used in various memory devices and/or other semiconductor devices.

The bifacial NAND memory devices of the semiconductor packages described in the present disclosure includes a first planar surface, or face. A first circuit layer is provided on the first planar surface. The first circuit layer may comprise a first NAND memory die. Likewise, the bifacial NAND memory devices also include a second planar surface, or face, which is opposite the first planar surface. A second circuit layer is provided on the second planar surface. The second circuit layer may comprise a NAND memory die. One or more through silicon vias (TSVs) facilitate signal transmission between the NAND memory dies on the first planar surface and the NAND memory dies on the second planar surface.

In some examples, multiple bifacial NAND memory devices may be stacked on top of each other to create, for example, a high-capacity memory device. For example, a first planar surface of a first bifacial NAND memory device may be coupled or bonded to a second planar surface of a second, distinct bifacial NAND memory device. In an example, the first bifacial NAND memory device and the second bifacial NAND memory device may be coupled or otherwise bonded together by various wafer to wafer bonding processes including, but not limited to, copper to copper bonding and/or via one or more solder bumps/balls. The wafer-to-wafer bonding process enables high speed signal transmission between the bifacial semiconductor wafers and eliminates the need for bonding the bifacial semiconductor wafers using bond wires.

Furthermore, the stack of bifacial NAND memory devices may also be disposed over and/or electrically coupled to an interposer of the semiconductor package. That is, the semiconductor package can include the plurality of bifacial NAND memory devices disposed directly over and electrically coupled to an interposer that may also support the stack of bifacial NAND memory devices. In an example, the interposer may also include a plurality of multiplexers (MUX) integrally formed within the interposer. In the semiconductor package, each of the bifacial NAND memory devices may be electrically coupled with the plurality of MUX included within the interposer as well.

The semiconductor package including bifacial NAND memory devices described herein also reduces the risk of device warpage when the bifacial NAND memory devices are stacked on top of one another. For example, when the first circuit layer is fabricated on the first planar surface of the bifacial NAND memory device, stress is applied on the bifacial NAND memory device in a first direction. However, when the second circuit layer is fabricated and provided on the second planar surface of the bifacial NAND memory device, a similar, or the same amount of stress, is applied on the bifacial NAND memory device in a second direction that is opposite the first direction. The stress applied in the second direction effectively offsets the stress applied in the first direction thereby reducing the risk of wafer warpage.

Accordingly, the semiconductor package including bifacial NAND memory devices of the present disclosure provides many technical benefits including, but not limited to, effectively doubling the storage capacity of a memory device without significantly increasing the overall size of the package, reducing or minimizing the risk of memory device warpage when NAND memory devices are stacked together, high transmission speeds between bifacial NAND memory devices due to the wafer to wafer bonding process, and reducing manufacturing costs in terms of time and materials.

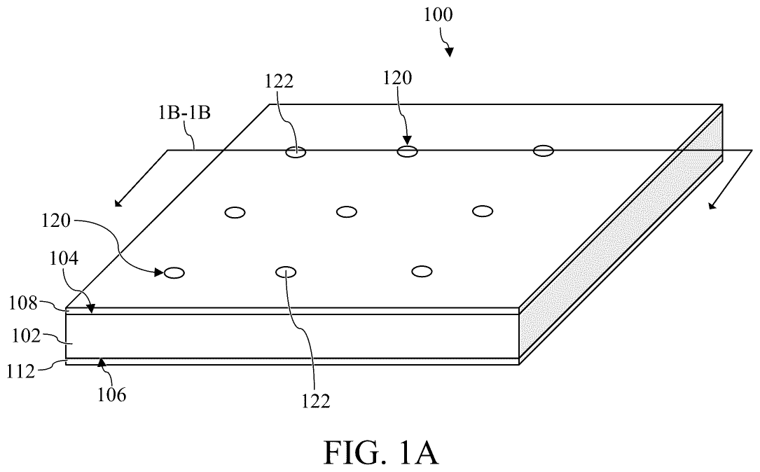

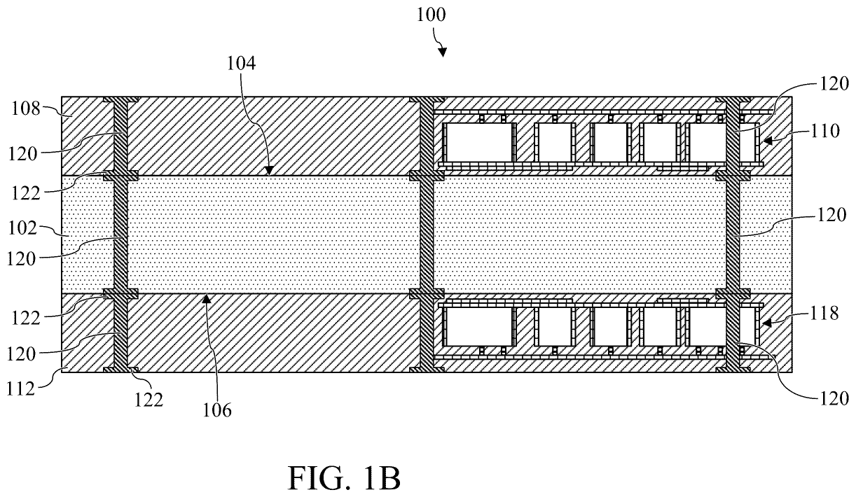

These and other examples will be described in more detail with respect to FIGs. 1A-9.

FIGS. 1A and 1B illustrate a bifacial semiconductor device 100 having semiconductor dies on opposing planar surfaces according to an example. More specifically, FIG. 1A illustrates a perspective view of bifacial semiconductor device 100, and FIG. 1B illustrates a front, cross-sectional view of bifacial semiconductor device 100, taken along line 1B-1B in FIG. 1A. The bifacial semiconductor device 100 may be used in a memory device such as, for example, a 3D NAND memory device. More specifically, bifacial semiconductor device 100 shown in FIG. 1A may be formed as a bifacial, 3D NAND memory device. As such, “bifacial semiconductor device” and “bifacial NAND memory device” may be used interchangeably herein. Although a 3D NAND memory device is specifically mentioned, the bifacial semiconductor device 100 may be used in various other semiconductor devices.

As shown in FIG. 1A, the bifacial semiconductor device 100 includes a base layer 102. The base layer 102 may be comprised of silicon such as, for example, silicon carbon nitride (SiCN) and/or silicon dioxide (SiO2). The base layer 102 includes a first planar surface 104 and a second planar surface 106 opposite the first planar surface 104.

A first circuit layer 108 is fabricated or otherwise provided on the first planar surface 104. In examples, the first circuit layer 108 is fabricated on and/or disposed over the first planar surface 104. In a non-limiting example, first circuit layer 108 may include a semiconductor die included therein. For example, and as shown FIG. 1B, first circuit layer 108 may include a first NAND memory die 110 formed, disposed, and/or fabricated therein, adjacent first planar surface 104 of base layer 102. First circuit layer 108, and more specifically first NAND memory die 110 included within first circuit layer 108, may be fabricated on and/or over first planar surface 104 using any suitable fabrication process(es) and/or methods. For example, the fabrication process may include one or more layering processes, one or more patterning processes, one or more doping processes, one or more heating treatment processes, one or more wafer cleaning processes and/or one or more wafer smoothing processes. The first planar surface 104 of base layer 102 may include a single circuit layer, or alternatively, may include multiple circuit layers or an array of semiconductor dies (e.g., first NAND memory die) disposed directly over first planar surface 104 of base layer 102.

The bifacial semiconductor device 100 also includes a second circuit layer 112. The second circuit layer 112 is fabricated or is otherwise provided on the second planar surface 106. Additionally, the second circuit layer 112 is also formed and/or fabricated within bifacial semiconductor device 100 opposite first circuit layer 108, and/or may be separated from first circuit layer 108 by base layer 102. Similar to first circuit layer 108, second circuit layer 112 may include a semiconductor die formed therein. For example, and as shown FIG. 1B, second circuit layer 112 may include a second NAND memory die 118 formed, disposed, and/or fabricated therein, adjacent second planar surface 106 of base layer 102. Second circuit layer 112, and more specifically second NAND memory die 118 included within second circuit layer 112, may be fabricated on and/or over second planar surface 106 using any suitable fabrication process(es) and/or methods. For example, the fabrication process may include one or more layering processes, one or more patterning processes, one or more doping processes, one or more heating treatment processes, one or more wafer cleaning processes and/or one or more wafer smoothing processes. Second planar surface 106 of base layer 102 may include a single circuit layer, or alternatively, may include multiple circuit layers or an array of semiconductor dies (e.g., second NAND memory die) disposed directly over second planar surface 106 of base layer 102.

In examples, the second circuit layer 112 is fabricated in a similar manner as the first circuit layer 108. For example, the first circuit layer 108 may be fabricated on a first silicon wafer and the second circuit layer 112 may be fabricated on second silicon wafer. The first silicon wafer may be bonded to the second silicon wafer such as will be described in greater detail herein.

In an example, the bifacial semiconductor device 100 may also include one or more through silicon vias (TSVs) 120. The TSVs 120 may extend through bifacial semiconductor device 100. More specifically, and as shown in FIG. 1B, each TSVs 120 may extend from the first circuit layer 108, through the base layer 102, to the second circuit layer 112. In the non-limiting example shown herein, TSVs 120 may extend through various portions of base layer 102, first circuit layer 108, and second circuit layer 112, including a portion of first circuit layer 108 including NAND memory die 110, as well as second circuit layer 112 including NAND memory die 118. As such, the TSVs 120 electrically couple the first circuit layer 108, or first face, of the bifacial semiconductor device 100 to the second circuit layer 112, or second face, of the bifacial semiconductor device 100. For example, TSVs 120 may electrically coupled first NAND memory die 110 included within first circuit layer 108 of bifacial semiconductor device 100 to second NAND memory die 118 of second circuit layer 112.

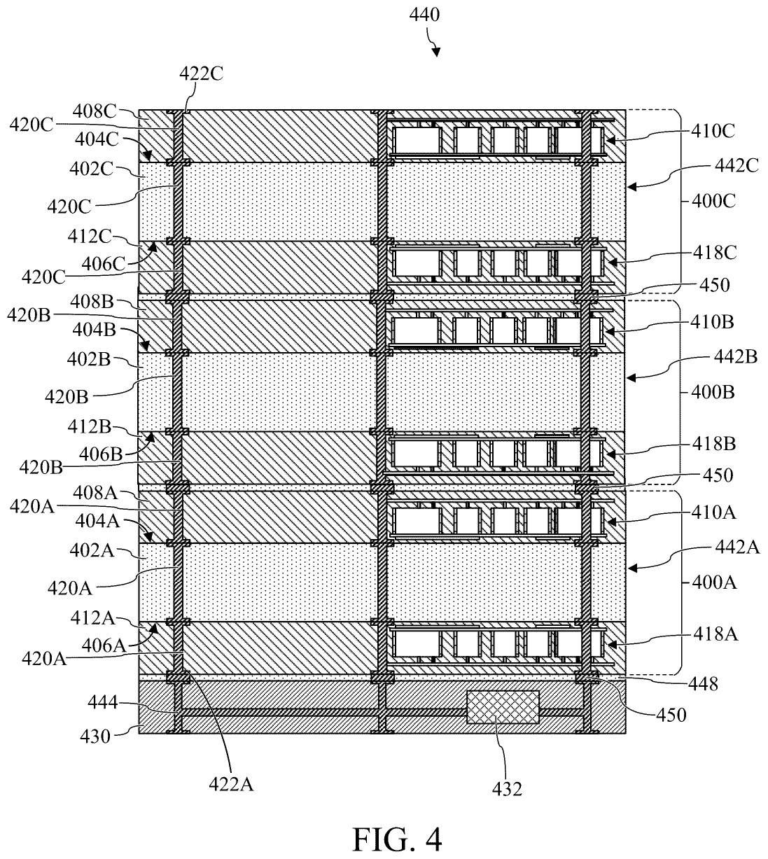

TSVs 120 may include contact pads 122 integrally formed therein. For example, and as shown in FIG. 1B, cach TSV 120 may include contact pad 122 formed on opposite ends of TSV 120. Contact pads 122 of TSVs 120 included within bifacial semiconductor device 100 may facilitate and/or improve the electrical coupling between TSVs 120 included in the various portions of bifacial semiconductor device 100 (e.g., first circuit layer 108, second circuit layer 112, etc.) and/or electrical coupling of bifacial semiconductor device 100 to distinct components or devices. That is, and as discussed herein, TSVs 120 of bifacial semiconductor device 100 may also facilitate the electrical coupling of bifacial semiconductor device 100, and the various components included therein, to distinct components (see, FIG. 4A).

TSVs 120 may be formed from any suitable material that facilitates the electrical couplings discussed herein. For example, TSVs 120 may be formed from copper (Cu) or tungsten (W). Although the through silicon vias 120 are shown in a circular pattern, the through silicon vias 120 may be arranged in any suitable manner. Additionally, although nine (9) TSVs 120 are shown in FIG. 1A, it is to be understood that bifacial semiconductor device 100, formed as a NAND memory device, may include more or less TSVs 120.

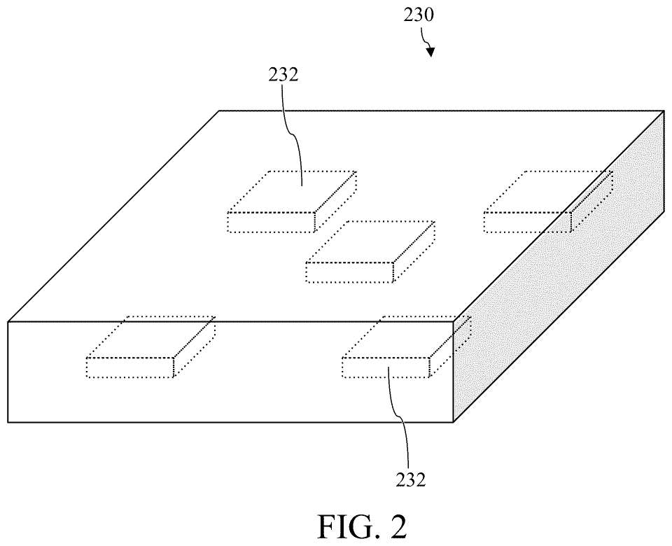

FIG. 2 illustrates an interposer 230 including a plurality of multiplexers 232 (hereafter, “MUX 232”). More specifically, the plurality of MUX 232, shown in phantom), may be integrally formed, disposed, and/or encompassed within the body or material layer forming interposer 230. Interposer 230 may be formed from any suitable material including, but not limited to, silicon (Si), glass, and/or organic substrates. Additionally, and as discussed herein (see, FIG. 4), interposer 230 may include a plurality of electrical channels (e.g., TSVs) formed therethrough to electrically couple the plurality of MUX 232 to distinct semiconductor components and/or devices disposed on interposer 230.

The plurality of MUX 232 integrally formed within interposer 230 may be formed as any suitable data selector and/or component configured to select between analog/digital input signals, and subsequently forward the input signal to a defined output. In the non-limiting example, each of the plurality of MUX 232 may be electrically coupled to one another to facilitate the communication and/or transmission of data between MUX 232, as well as distinct components or devices in electrical communication with MUX 232 via interposer 230, as discussed herein. As a result of MUX 232 being integrally formed within and/or encompassed by interposer 230, the plurality of MUX 232 may not be physically/mechanically exposed within interposer 230, and therefore may not increase the dimensions (e.g., height) of interposer 230. Additionally, integrally forming MUX 232 within interposer 230 can also reduce the size (x-y, width/length) required by a semiconductor device (e.g., NAND memory device), as MUX 232 is no longer formed in plane with NAND stackings, as is known conventionally. Furthermore, integrally forming MUX 232 within interposer 230 also increases a MUX function for a semiconductor device (e.g., NAND memory device) utilizing interposer 230, as discussed herein. For example, the inclusion of four (4) distinct MUX integrally within interposer 230 can realize an 8:1 MUX function. As discussed herein, interposer 230 including the plurality of MUX 232 integrally formed and/or embedded therein may be used within a memory device formed from a plurality of bifacial NAND memory devices (see, FIGS. 1A and 1B), and can replace the need of a substrate within the bifacial NAND memory devices.

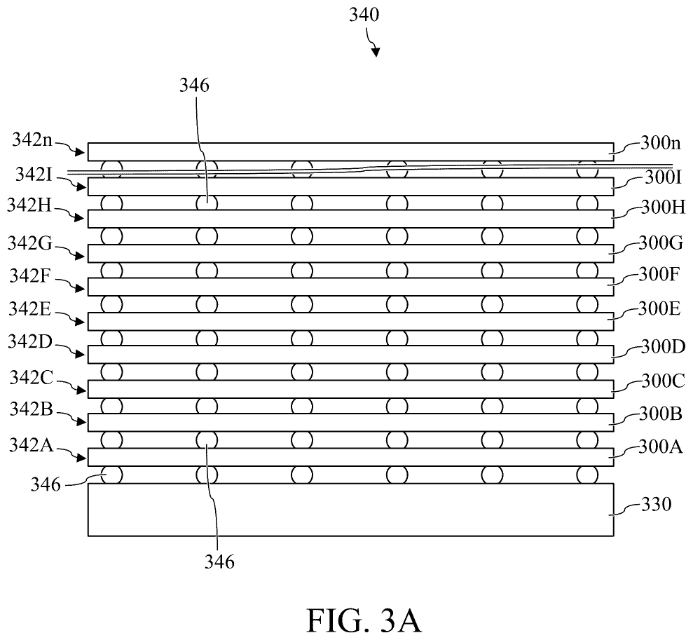

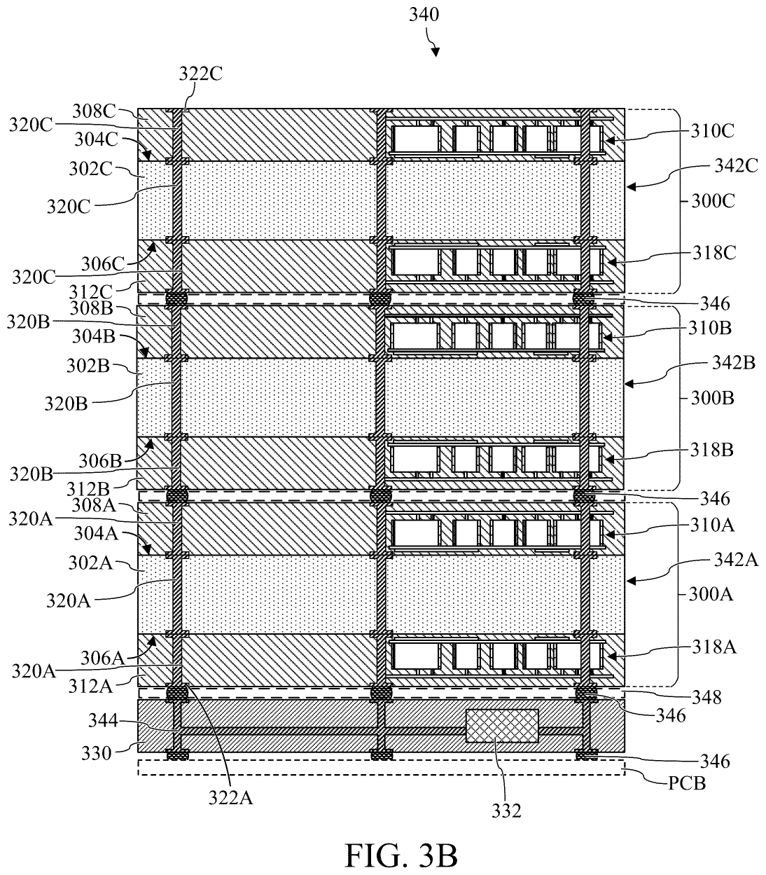

FIGS. 3A and 3B illustrate a semiconductor package 340. More specifically, FIG. 3A illustrates a front view of semiconductor package 340 and FIG. 3B illustrates a front cross-sectional view of a portion of semiconductor package 340 shown in FIG. 3A. In non-limiting examples, semiconductor package 340 may be formed as a memory package or a component that may be included within and/or utilized by distinct semiconductor devices. For example, semiconductor package 340 is shown as a high-speed NAND (HSN) package 340 that may be utilized and/or integrated with a memory device or a data storage device. When compared with a typical memory device in which traditional semiconductor wafers are used, semiconductor package 340 shown in FIGS. 3A and 3B can store double the amount of data while consuming or requiring less space.

Semiconductor package 340 shown in FIGS. 3A and 3B includes interposer 330, and a plurality of bifacial semiconductor device 300 disposed over interposer 330. In the example shown, each bifacial semiconductor device 300 in the semiconductor package 340 may be similar to the bifacial semiconductor device 100 shown and described with respect to FIGS. 1A and 1B. Additionally in the example shown, interposer 330 in semiconductor package 340 may be similar to interposer 230 shown and described herein with respect to FIG. 2. It is understood that similarly numbered and/or named components may function in a substantially similar fashion. Redundant explanation of these components has been abbreviated or omitted for clarity.

In the non-limiting example, a plurality of bifacial semiconductor devices, formed as bifacial NAND memory device 300, may be formed, disposed, and/or positioned over interposer 330 of semiconductor package 340. More specifically, and as shown in FIGS. 3A and 3B, a first bifacial NAND memory device 300A may be disposed directly over and/or directly adjacent interposer 330. Additionally, at least one distinct bifacial NAND memory device 300B-300I, 300n may be disposed directly over first bifacial NAND memory device 300A, and/or one another. That is, distinct, bifacial NAND memory device 300B may be disposed directly over first bifacial NAND memory device 300A, and distinct, bifacial NAND memory device 300C may be disposed directly over bifacial NAND memory device 300B, and so on.

In the non-limiting example, cach outside edge or surface 342 (or an entire diameter) for each bifacial NAND memory device 300 may be flush, aligned, and/or substantially aligned with one another in semiconductor package 340. For example, and as shown in FIG. 3A, the outside edge 342A of the first bifacial NAND memory device 300A is substantially aligned or flush with respect to the outside edge 342B-342I, 342n of each distinct bifacial NAND memory device 300B-300I, 300n. As discussed herein, this arrangement is made possible by utilizing a bonding process instead of bond wires such as previously described.

Semiconductor package 340 also includes interposer 330 including a plurality of MUX 332 (scc, FIG. 3B) integrally formed within interposer 330. In the non-limiting example, first bifacial NAND memory device 300A is disposed directly over and/or directly adjacent interposer 330. Additionally, cach bifacial NAND memory device 300A-300I, 300n is disposed over and/or substantially aligned above interposer 330. Briefly turning to FIG. 3B, a plurality of electrical channels 344 (e.g., TSVs) may be formed within and/or through interposer 330. Electrical channels 344 formed in interposer 330 may be electrically coupled to the plurality of MUX 332, as well as each of the plurality of bifacial NAND memory devices 300 formed directly over interposer 330, as discussed herein. Integrally forming MUX 332 directly in interposer 330 allows each MUX 332 and bifacial NAND memory device 300A-300I, 300n to be electrically coupled and/or in electronic communication, As discussed herein. Additionally, interposer 330 directly supports each bifacial NAND memory device 300A-300I, 300n of semiconductor package 340 without the need of a distinct substrate or substrate layer. This in turn forms semiconductor package 340 as a substrate-less semiconductor device and/or assembly.

In addition to each outside edge or surface 342 (or an entire diameter) for each bifacial NAND memory device 300 being aligned with one another, each bifacial NAND memory device 300 is also aligned with interposer 330 of semiconductor package 340. For example, and as shown in FIG. 3A, the outside edges 342A-342I, 342n of each bifacial NAND memory device 300A-300I, 300n is substantially aligned or flush with the outside edge of interposer 330 including MUX 32 integrally formed therein. The vertical stacking and/or vertical alignment of bifacial NAND memory devices 300A-300I, 300n and interposer 330 create a completely, vertically stacked semiconductor package 340. That is, and compared to conventional semiconductor packages, which include stepped configurations for the memory devices included therein, semiconductor package 340 is configured and/or formed to be completely vertical and/or to include components therein that are vertically aligned along common planes. As discussed herein, the vertical packaging of semiconductor package 340 decreases the footprint or size requirement within electronic devices for semiconductor package 340 having similar memory capacities. Alternatively, and as discussed herein, vertically stacked and aligned semiconductor package 340 maintains the same or substantially similar size requirements within electronic device that include a greater memory capacity than conventional packages.

When multiple bifacial NAND memory device 300 are stacked together and disposed or positioned over interposer 330, such as shown in FIGS. 3A and 3B, adjacent bifacial NAND memory devices 300 are electrically coupled to one another. Additionally, first bifacial NAND memory device 300A may be electrically coupled to interpose 330. For example, and with reference to FIG. 3B, a first plurality of TSVs 320A extending through first NAND memory die 310A of first bifacial NAND memory device 300A may be electrically coupled with a second plurality of TSVs 320A extending through second NAND memory dic 318A of first bifacial NAND memory device 300A. Additionally, second plurality of TSVs 320A extending through second NAND memory dic 318A of first bifacial NAND memory device 300A may also be electrically coupled to the plurality of MUX 332 integrally formed within interposer 330, via electrical channels 344 formed within interposer 330.

Additionally, each of the distinct bifacial NAND memory devices 300B-3001, 300n may be electrically coupled to each adjacent (e.g., above, below) bifacial NAND memory devices 300B-300I, 300n. For example, distinct, bifacial NAND memory device 300B disposed directly over first bifacial NAND memory device 300A may be electrically coupled to first bifacial NAND memory device 300A. More specifically, a first distinct plurality of TSVs 320B extending through first NAND memory die 310B of distinct bifacial NAND memory device 300B may be electrically coupled with a second distinct plurality of TSVs 320B extending through second NAND memory die 318B of distinct bifacial NAND memory device 300B. Additionally, second distinct plurality of TSVs 320B extending through second NAND memory dic 318B of distinct bifacial NAND memory device 300B may also be electrically coupled to the first plurality of TSVs 320A extending through first NAND memory die 310A of first bifacial NAND memory device 300A. Furthermore, first distinct plurality of TSVs 320B extending through first NAND memory die 310B of distinct bifacial NAND memory device 300B may be electrically coupled with a second distinct plurality of TSVs 320C extending through second NAND memory die 318C of distinct bifacial NAND memory device 300C disposed directly over distinct bifacial NAND memory device 300B.

Although FIG. 3B shows three (3) bifacial NAND memory devices 300A, 300B, 300C being stacked together, the semiconductor package 340 may include any number of stacked bifacial NAND memory devices without suffering from the various drawbacks of using conventional semiconductor wafers such as described above. For example, the planar surfaces of each bifacial NAND memory device 300 may be electrically coupled using solder bumps 346. More specifically, a solder bump 346 may be formed on each exposed contact pad 322 for each TSV 320 included within and/or extending through bifacial NAND memory devices 300. Contact pads 322 for each TSV 320 may be formed within and/or exposed on first circuit layer 308 and second circuit layer 312, respectively, of bifacial NAND memory device 300. In a non-limiting example, second distinct plurality of TSVs 320B of distinct bifacial NAND memory device 300B is electrically coupled to first plurality of TSVs 320A extending through first NAND memory die 310A of first bifacial NAND memory device 300A via solder bumps 346.

Additionally, as shown in FIG. 3B, first bifacial NAND memory device 300A may be electrically coupled to interposer 330 using solder bumps 346. More specifically, and as shown in FIG. 3B, second plurality of TSVs 320A extending through second NAND memory die 318A of first bifacial NAND memory device 300A may be electrically coupled to the plurality of MUX 332 integrally formed within interposer 330 using solder bumps 346. Solder bumps 346 may be formed on and/or between contact pads 322 of second plurality of TSVs 320A extending through second NAND memory die 318A and electrical channels 344 formed within and/or exposed on interposer 330. In the example, solder bumps 346 facilitate the electrical coupling between first bifacial NAND memory device 300A and the plurality of mux 332 integrally formed within interposer 330 and electrically coupled to electrical channels 344. The bonding process using solder bumps 346 may be used to transmit signals between each of bifacial NAND memory devices 300 and/or interposer 330, thereby eliminating the need for wire bonding different layers of the semiconductor package 340.

Solder bumps 346 may also be formed on interposer 330, opposite the plurality of bifacial NAND memory devices 300. More specifically, and as shown in FIG. 3B, solder bumps 346 may be formed on a surface of interposer 330 opposite first bifacial NAND memory device 300A and may be formed over and/or contact electrical channels 344 formed within and/or extending through interposer 330. Solder bumps 346 may be formed on interposer 330, opposite bifacial NAND memory devices 300, in order to electrically couple interposer 330, and in turn bifacial NAND memory device 300, to a distinct component and/or device. For example, and as discussed herein (sec, FIG. 3B), solder bumps 346 may be formed between and/or may electrically couple interposer 330 of semiconductor package 340 to a printed circuit board (PCB) (shown in phantom). PCB may utilize semiconductor package 340 in an electronic device (not shown) as a storage or memory device, as discussed herein.

In some examples and as shown in FIG. 3B, a layer of epoxy molding compound 348 (shown in phantom) or a fine filler material (e.g., silicon dioxide or carbon nitride) may be positioned on or otherwise associated with and/or positioned between the various planar surfaces 304, 306 and/or circuit layers 308, 312 of bifacial NAND memory devices 300. For example, epoxy molding compound348 (shown in phantom) may be disposed around solder bumps 346 and/or may be disposed between each adjacent bifacial NAND memory device 300. Additionally, a layer of epoxy molding compound 348 may be disposed between first bifacial NAND memory device 300A and interposer 330. The solder bump 346 or pillar may be provided on or otherwise extend through the layer of epoxy molding compound 348 to enable signal transmission between bifacial NAND memory devices 300 and/or interposer 330. Epoxy molding compound 348 is filled, disposed, and/or included within bifacial NAND memory device 300 to fill gaps and/or spaces between the various components forming bifacial NAND memory device 300, as discussed herein.

Although solder bumps 346 are specifically mentioned, copper bumps or pillars, solder balls and/or other bonding processes may be used to electrically coupled the bifacial semiconductor wafers.

Bonding, such as described above, enables higher signal transmission between the plurality of bifacial NAND memory devices 300 and/or interposer 330 when compared to traditional bond wires. Accordingly, cost savings in terms of materials and/or time may be achieved by stacking bifacial NAND memory devices 300 on interposer 330 in the manner described herein when compared to traditional wafer stacking.

Additionally, and as discussed above, in typical stacked semiconductor devices (e.g., traditional 3D NAND memory devices) the number of layers may be limited by an amount of stress that is induced on the semiconductor wafers when a circuit layer is fabricated on a single surface. As the number of wafers increases, the amount of stress also increases which can subsequently warp the semiconductor wafers in the semiconductor device.

However, the bifacial semiconductor package 340 described herein reduces the risk of warpage as an amount of stress provided on the first planar surface of bifacial NAND memory devices 300 by the first circuit layer 308 is offset by an amount of stress provided on second planar surface 306 of bifacial NAND memory device 300 by second circuit layer 312. Accordingly, any number of bifacial NAND memory devices 300 may be stacked on top of one another while eliminating or substantially reducing the risk of the bifacial NAND memory devices 300 warping. As such, semiconductor package 340 described herein may be used for extra-large packaging capacity as n or more bifacial NAND memory devices 300 may be stacked.

FIG. 4 illustrates a front cross-sectional view of a portion of semiconductor package 440. Semiconductor package 440 shown in FIG. 4 may be similar to semiconductor package 340 shown and described herein with respect to FIGS. 3A and 3B. It is understood that similarly numbered and/or named components may function in a substantially similar fashion. Redundant explanation of these components has been abbreviated or omitted for clarity.

Semiconductor package 440 shown in FIG. 4 may bond the various components and/or devices using a hybrid wafer-to-wafer bonding process. In an example, the hybrid wafer to wafer bonding process may be a copper (cu) to copper (cu) bonding in which a high temperature annealing process may be used to bond copper fingers, bumps, or pillars 450 (hereafter, “cooper fingers 450”) from adjacent faces or surfaces of bifacial NAND memory devices 400 together. In a non-limiting example, second distinct plurality of TSVs 420B of distinct bifacial NAND memory device 400B is electrically coupled to first plurality of TSVs 420A extending through first NAND memory dic 410A of first bifacial NAND memory device 400A via copper fingers 450.

Additionally as shown in FIG. 4, first bifacial NAND memory device 400A may be electrically coupled to interposer 430 using copper fingers 450. More specifically, second plurality of TSVs 420A extending through second NAND memory die 418A of first bifacial NAND memory device 400A may be electrically coupled to the plurality of MUX 432 integrally formed within interposer 430 using copper fingers 450. Copper fingers 450 may be formed on and/or between contact pads 422 of second plurality of TSVs 420A extending through second NAND memory die 418A and electrical channels 444 formed within and/or exposed on interposer 430. In the example, and similar to solder bumps 346 (see FIGS. 3A and 3B), copper fingers 450 facilitate the electrical coupling between first bifacial NAND memory device 400A and the plurality of mux 432 integrally formed within interposer 430 and electrically coupled to electrical channels 444. The bonding process using copper fingers 450 may be used to transmit signals between each of bifacial NAND memory devices 400 and/or interposer 430, thereby eliminating the need for wire bonding different layers of the semiconductor package 440.

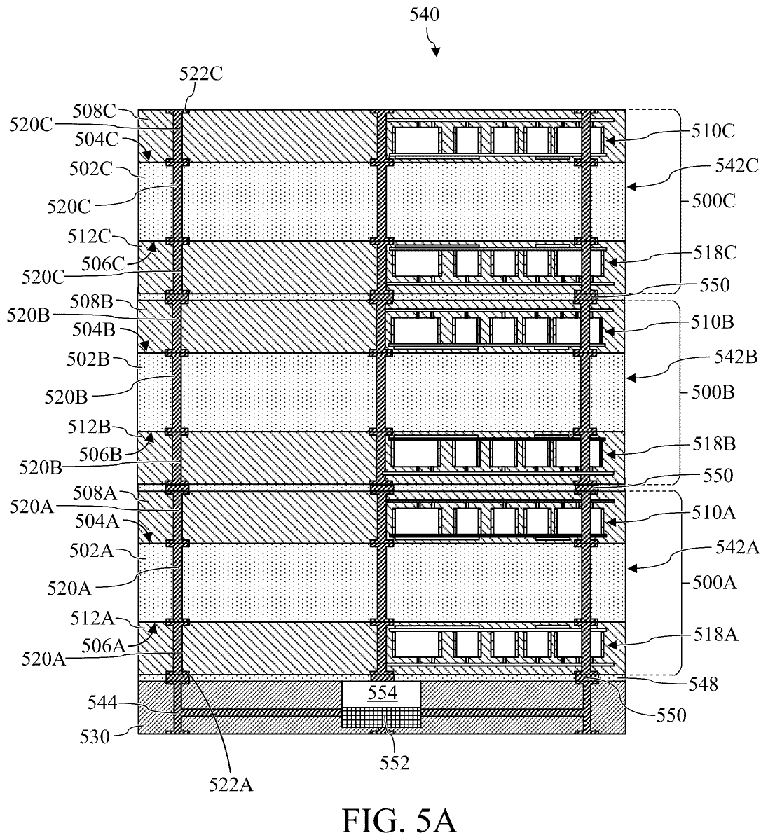

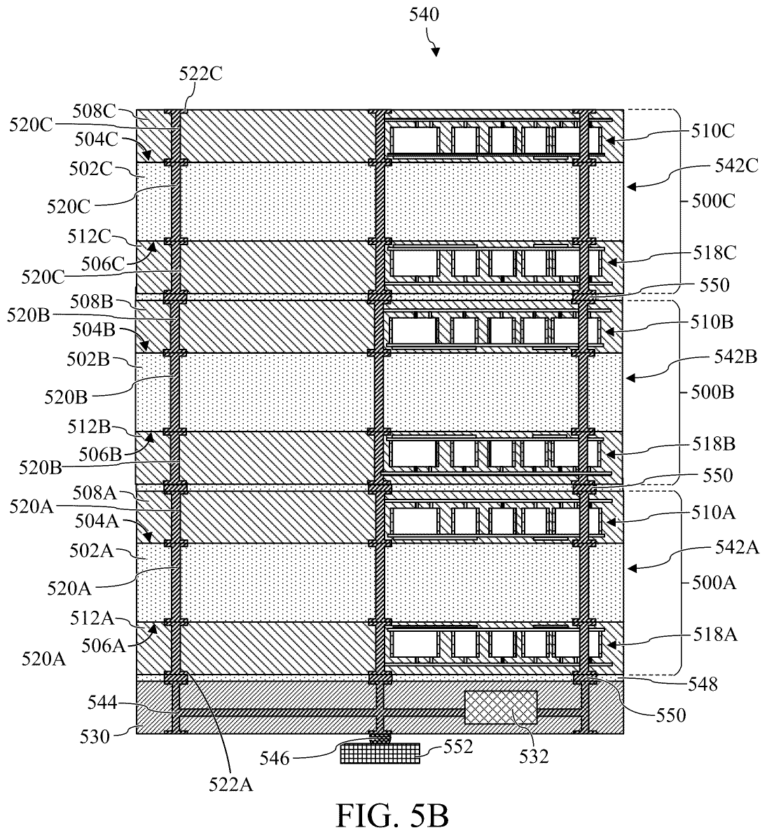

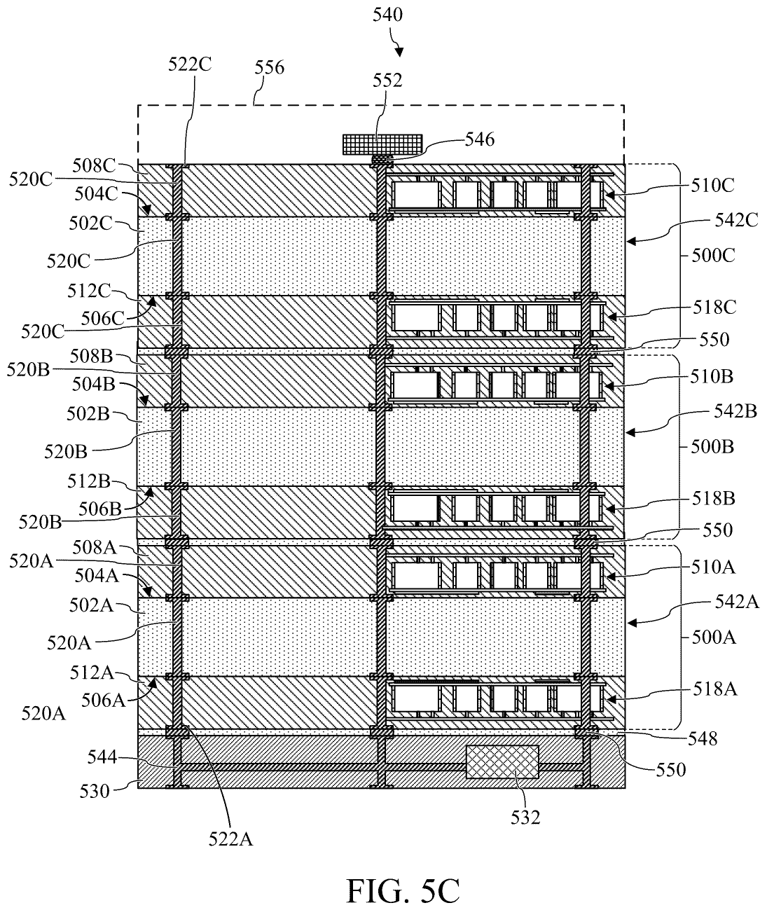

FIGS. 5A-5C illustrate front cross-sectional views of a portion of semiconductor package 540. Semiconductor package 540 shown in FIGS. 5A-5C may be similar to semiconductor package 340 shown and described herein with respect to FIGS. 3A and 3B. For example, semiconductor package 540 includes components that are vertically aligned and/or include vertically aligned edges to reduce the size of the semiconductor package 540 and/or maintain a similar size of the memory package, while increasing the memory capacity, as similarly discussed herein.

Semiconductor package 540 may also include a controller 552. Controller 552 may be electrically coupled to the plurality of MUX 532 formed integrally within interposer 530 and/or the plurality of bifacial NAND memory devices 500 disposed over interposer 530. Additionally, controller 552 may facilitate the interconnection of semiconductor package 540 with distinct components and/or devices that utilize semiconductor package 540 therein. In a non-limiting example, controller 552 may be formed as a flip chip, or controlled collapse chip connection (C4).

In the non-limiting example shown in FIG. 5A, controller 552 of semiconductor package 540 may be formed, positioned, and/or disposed within a recess 554 formed in interposer 530. Recess 554 and/or controller 552 may be formed adjacent at least one of the plurality of MUX 532 integrally formed within interposer 530. Additionally, as shown, controller 552 may be electrically coupled with electrical channels 544 formed within and/or extending through interposer 530 of semiconductor package 540.

In another non-limiting example, controller 552 of semiconductor package 540 may be formed on interposer 530, opposite the plurality of bifacial NAND memory devices 500. More specifically, and as shown in FIG. 5B, controller 552 may be formed on a surface of interposer 530 opposite first bifacial NAND memory device 500A and may be formed over and/or contact at least one electrical channel 544 formed within and/or extending through interposer 530. In the non-limiting example, at least one solder bumps 546 may be formed on interposer 530, opposite bifacial NAND memory devices 500, and/or between interposer 530 and controller 552 to electrically couple controller 552 and interposer 530. As such, and as discussed herein, controller 552 formed on interposer 530, opposite bifacial NAND memory devices 500, may also be electrically coupled to bifacial NAND memory device 500 via interposer 530.

In another non-limiting example shown in FIG. 5C, controller 552 may be disposed over the plurality of bifacial NAND memory devices 500 included within semiconductor package 540. That is, controller 552 may be formed, positioned, and/or disposed directly over the topmost bifacial NAND memory device 500n of semiconductor package 540, opposite interposer 530. As shown in FIG. 5C, controller 552 may be disposed over and/or electrically coupled to distinct TSV 520n formed through second circuit layer 512n of distinct bifacial NAND memory device 500n. In the non-limiting example, at least one solder bumps 546 may be formed on TSV 520n, opposite interposer 530, and/or between TSV 520n of distinct bifacial NAND memory device 500n and controller 552 to electrically couple controller 552 and distinct bifacial NAND memory device 500n. As such, and as discussed herein, controller 552 formed on distinct bifacial NAND memory device 500n, opposite interposer 520, may also be electrically coupled to all bifacial NAND memory devices 500, as well as interposer 530 of semiconductor package 540.

Additionally, as shown in FIG. 5C, a molding compound 556 (shown in phantom) may be disposed over controller 552 and distinct bifacial NAND memory device 500n of semiconductor package 540. In the non-limiting example, molding compound 556 may aid in securing controller to distinct bifacial NAND memory device 500n. Additionally, molding compound 556 formed over semiconductor package 540 may also protect the plurality of bifacial NAND memory devices 500 and/or interposer 530 forming semiconductor package 540.

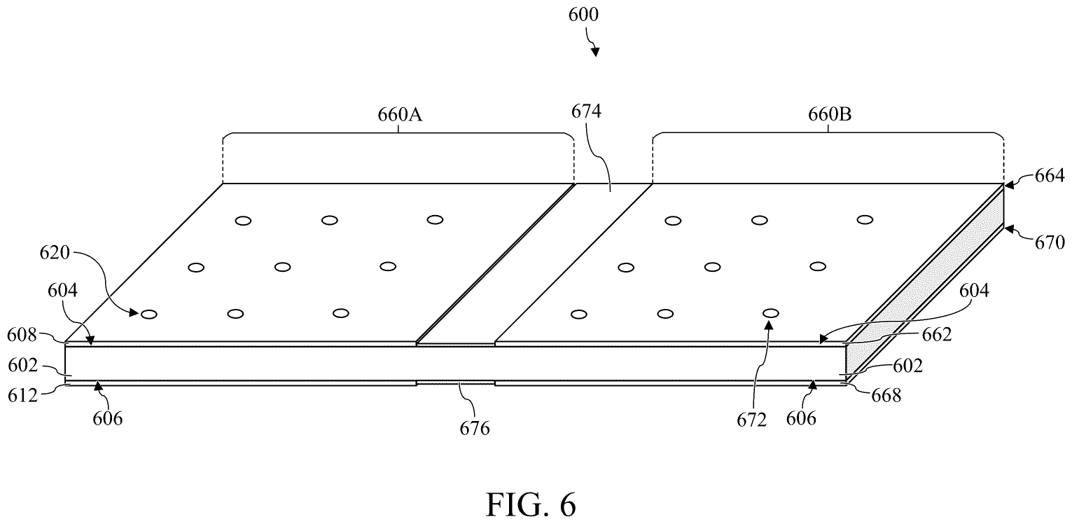

FIG. 6 illustrates a bifacial NAND memory device 600 having semiconductor dies on opposing planar surfaces according to an example. As shown in FIG. 6, bifacial NAND memory device 600 includes a base layer 602 having a first planar surface 604 and a second planar surface 606 formed opposite first planar surface 604. Base layer 602 shown in FIG. 6 may be similar to base layer 102 shown and described herein with respect to FIGS. 1A and 1B.

Bifacial NAND memory device 600 may include a first bifacial NAND memory device portion 660A and a distinct bifacial NAND memory device portion 660B. First bifacial NAND memory device portion 660A may be similar to bifacial NAND memory device 100 shown and described herein with respect to FIGS. 1A and 1B. That is, first bifacial NAND memory device portion 660A includes first circuit layer 608 fabricated or otherwise provided on first planar surface 604, where first circuit layer 608 includes first NAND memory die 610 included therein. Additionally, first bifacial NAND memory device portion 660A includes second circuit layer 612 fabricated or otherwise provided on second planar surface 606 and includes second NAND memory die 612. First bifacial NAND memory device portion 660A also includes one or more TSVs 620 extending from the first circuit layer 608, through the base layer 602, to second circuit layer 612.

Distinct bifacial NAND memory device portion 660B also includes first circuit layer 662 fabricated or otherwise provided on first planar surface 604 of base layer 602. In examples, first circuit layer 662 is fabricated on and/or disposed over first planar surface 604. In a non-limiting example, first circuit layer 662 may include a semiconductor die included therein. For example, first circuit layer 662 may include a first NAND memory die 664 formed, disposed, and/or fabricated therein, adjacent first planar surface 604 of base layer 602. First circuit layer 662, and more specifically first NAND memory die 664 included within first circuit layer 662, may be fabricated on and/or over first planar surface 604 using any suitable fabrication process(es) and/or methods. The first planar surface 604 of base layer 602 may include a single circuit layer, or alternatively, may include multiple circuit layers or an array of semiconductor dies (e.g., first NAND memory die) disposed directly over first planar surface 604 of base layer 602.

Distinct bifacial NAND memory device portion 660B also includes a second circuit layer 668. Second circuit layer 668 is fabricated or is otherwise provided on the second planar surface 606. Additionally, the second circuit layer 668 is also formed and/or fabricated within bifacial NAND memory device 600 opposite first circuit layer 662, and/or may be separated from first circuit layer 662 by base layer 602. Similar to first circuit layer 662, second circuit layer 668 may include a semiconductor die formed therein. For example, second circuit layer 668 may include a second NAND memory die 670 formed, disposed, and/or fabricated therein, adjacent second planar surface 606 of base layer 602. Second circuit layer 668, and more specifically second NAND memory die 670 included within second circuit layer 668, may be fabricated on and/or over second planar surface 106 using any suitable fabrication process(es) and/or methods. Additionally, second planar surface 606 of base layer 602 may include a single circuit layer, or alternatively, may include multiple circuit layers or an array of semiconductor dies (e.g., second NAND memory die) disposed directly over second planar surface 606 of base layer 602.

In examples, the second circuit layer 668 is fabricated in a similar manner as the first circuit layer 662. For example, the first circuit layer 662 may be fabricated on a first silicon wafer and the second circuit layer 668 may be fabricated on second silicon wafer. The first silicon wafer may be bonded to the second silicon wafer such as will be described in greater detail herein.

In an example, the bifacial NAND memory device 600 may also include one or more through silicon vias (TSVs) 672. The TSVs 672 may extend through bifacial NAND memory device 600. More specifically, each TSV 672 may extend from the first circuit layer 662, through the base layer 602, to the second circuit layer 668. In the non-limiting example shown herein, TSVs 672 may extend through various portions of base layer 602, first circuit layer 662, and second circuit layer 668, including a portion of first circuit layer 662 including NAND memory die 664, as well as second circuit layer 668 including NAND memory die 670. As such, the TSVs 672 electrically couple the first circuit layer 662, or first face, of bifacial NAND memory device 600 to the second circuit layer 668, or second face, of bifacial NAND memory device 600. For example, TSVs 672 may electrically couple first NAND memory die 664 included within first circuit layer 662 of bifacial NAND memory device 600 to second NAND memory die 670 of second circuit layer 668.

As shown in FIG. 6, bifacial NAND memory device 600 also includes a first redistribution layer 674 and second redistribution layer 676. First redistribution layer 674 may be disposed over first planar surface 604 of base layer 602. Additionally, first redistribution layer 674 may extend between, be electrically coupled to, and/or may electrically connect NAND memory die 610 included in first circuit layer 608 of first bifacial NAND memory device portion 660A and NAND memory die 664 included in first circuit layer 662 of distinct bifacial NAND memory device portion 660B.

Additionally, second redistribution layer 676 may be disposed over second planar surface 606 of base layer 602, opposite first redistribution layer 674. Second redistribution layer 676 may also extend between, be electrically coupled to, and/or may electrically connect NAND memory die included in second circuit layer 612 of first bifacial NAND memory device portion 660A and NAND memory die 670 included in second circuit layer 668 of distinct bifacial NAND memory device portion 660B. First redistribution layer 674 enables signal transmissions between the various semiconductor dies 664 on first planar surface 604, while second redistribution layer 676 enables signal transmissions between the various semiconductor dies 670 on second planar surface 606 of base layer 602.

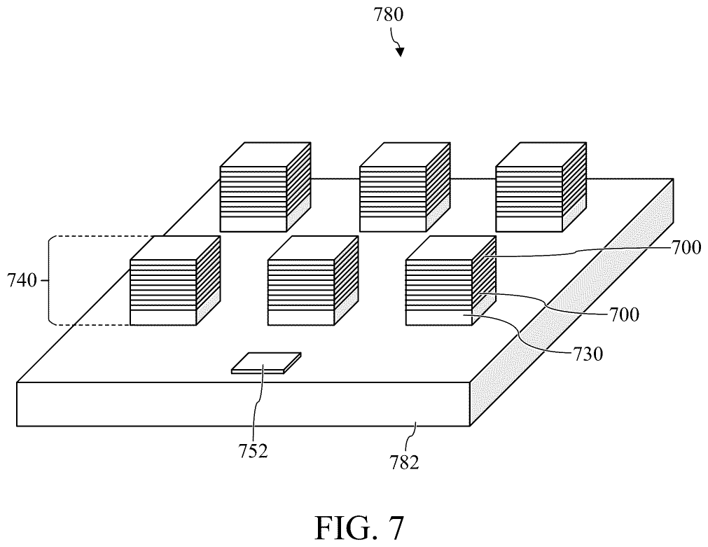

FIG. 7 illustrates an electronic device 780 including a plurality of semiconductor packages 740 according to an example. As shown in FIG. 7, cach of the plurality of semiconductor packages 740 included in electronic device 780 include a plurality of bifacial NAND memory devices 700 disposed over interposer 730. Semiconductor packages 740 including bifacial NAND memory device 700 and interposer 730 shown in FIG. 7 may be similar to semiconductor packages 340 shown and described herein with respect to FIGS. 3A and 3B. As such, and as discussed herein, each of the plurality of semiconductor packages 740 include components that are vertically aligned and stacked, and/or the edges of cach component forming the plurality of semiconductor packages 740 are substantially aligned. As similarly discussed herein, the vertically stacked semiconductor packages 740 included in electronic device 780 reduces the size requirements for the semiconductor packages 740 within electronic device 780 and/or maintains a similar size, while increasing the memory capacity. This in turn facilitates decreasing the size of the electronic device 780 while maintaining a similar memory capacity, or alternatively maintains a similar size of electronic device 780, while increasing the memory capacity.

The plurality of semiconductor packages 740 may be positioned on and/or disposed over a printed circuit board (PCB) 782. Additionally, the plurality of semiconductor packages 740 may be electrically coupled to PCB 782. For example, and as similarly discussed herein with respect to FIG. 3B, interposer 730 of each of the plurality of semiconductor packages 740 may be disposed directly over and may be electrically couple to PCB 782 using any suitable electrical coupling technique and/or process (see, FIG. 3B; solder bumps 346). PCB 782, including controller 752, may also be electrically coupled to distinct components and/or portions of a larger electronic device or system that may utilize electronic device 780 during operation. As discussed herein, the plurality of semiconductor packages 740 may be formed as memory or storage packages, that may facilitate data storage. As such, electronic device 780 shown in FIG. 7, may be formed as memory or storage device having an increased storage capacity as a result of including the plurality of semiconductor packages 740.

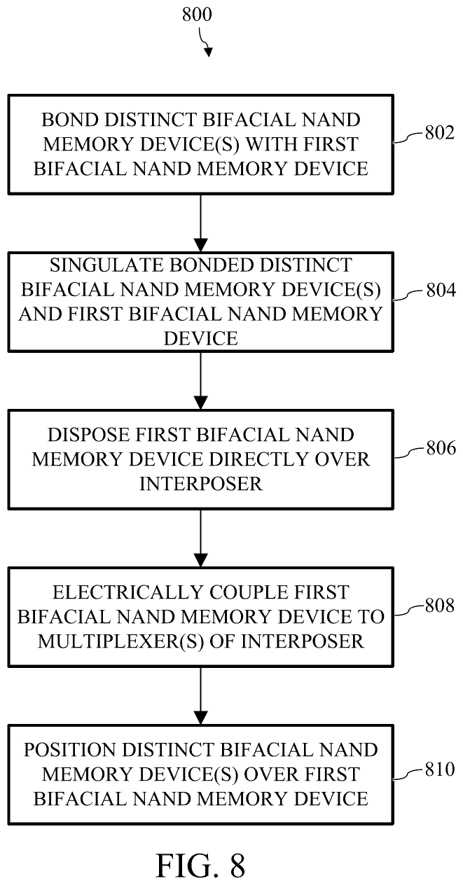

FIG. 8 illustrates a method 800 for fabricating a semiconductor package according to an example. The method 800 and processes therein can be performed to fabricate various semiconductor packages described herein.

In process 802 distinct bifacial NAND memory device(s) may be bonded with a first bifacial NAND memory device. More specifically, at least one distinct bifacial NAND memory device included on a wafer of bifacial NAND memory devices may be bonded, positioned over, and/or electrically coupled to a first bifacial NAND memory device included on a wafer of a plurality of distinct, first bifacial NAND memory devices. In non-limiting examples, the wafers including the plurality of distinct bifacial NAND memory devices and the wafer including the plurality of first bifacial NAND memory devices may be bonded using hybrid wafer-to-wafer (e.g., copper-to-copper) bonding processes, or may be bonded and electrically coupled using solder bumps, balls, pillars, or the like. In the example, the first bifacial NAND memory device and at least one bifacial NAND memory device may each include a plurality of through silicon vias (TSVs) extending therethrough. The bonding process of 802 may include electrically coupling each of the first bifacial NAND memory device and the at least one bifacial NAND memory device by electrically coupling the respective TSVs extending through each of the distinct memory devices.

In process 804, the bonded distinct bifacial NAND memory device(s) and the first bifacial NAND memory device may be singulated. More specifically, the bonded wafers including the distinct bifacial NAND memory device(s) disposed over the first bifacial NAND memory device may be singulated, separated, and/or split to form a plurality of stack-ups including a single, first bifacial NAND memory device, and at least one bifacial NAND memory device disposed over, bonded to, and/or electrically coupled to the first bifacial NAND memory device. The stack-up including the bonded first bifacial NAND memory device and at least one bifacial NAND memory device may be singulated using any suitable technique and/or method.

In process 806 the first bifacial NAND memory device may be disposed directly over an interposer. More specifically, the stack-up including the first bifacial NAND memory device, and at least one bifacial NAND memory device may be disposed over the interposer such that the first bifacial NAND memory device is positioned directly adjacent to the interposer.

In process 808, the first bifacial NAND memory device is electrically coupled to the interposer. More specifically, the first bifacial NAND memory device disposed directly over the interposer may also be electrically coupled to the interposer and a plurality of multiplexers (MUX) formed integrally within the interposer. In non-limiting examples, the first bifacial NAND memory device may be electrically coupled to interposer via the TSVs extending through first bifacial NAND memory device and at least one electrical channel extending through the interposer. In non-limiting examples, the first bifacial NAND memory device may be electrically coupled to the interposer, and more specifically the plurality of MUX integrally formed within the interposer, using hybrid wafer-to-wafer (e.g., copper-to-copper) bonding processes, or may be bonded and electrically coupled using solder bumps, balls, pillars, or the like.

In process 810, at least one distinct bifacial NAND memory device may be positioned over the first bifacial NAND memory device. More specifically, and as a result of bonding the at least one distinct bifacial NAND memory device to the first bifacial NAND memory device (e.g., process 802), at least one distinct bifacial NAND memory device may be positioned, disposed, and/or aligned over the first bifacial NAND memory device. Additionally as discussed herein, each of the at least one bifacial NAND memory devices may be electrically coupled to the first bifacial NAND memory device, and in turn electrically coupled to the plurality of MUX integrally formed within the interposer. The at least one distinct bifacial NAND memory device may be electrically coupled to the interposer via the TSVs extending there through. In non-limiting examples, the distinct bifacial NAND memory device(s) may be electrically coupled to the first bifacial NAND memory device using hybrid wafer-to-wafer (e.g., copper-to-copper) bonding processes, or may be bonded and electrically coupled using solder bumps, balls, pillars, or the likc.

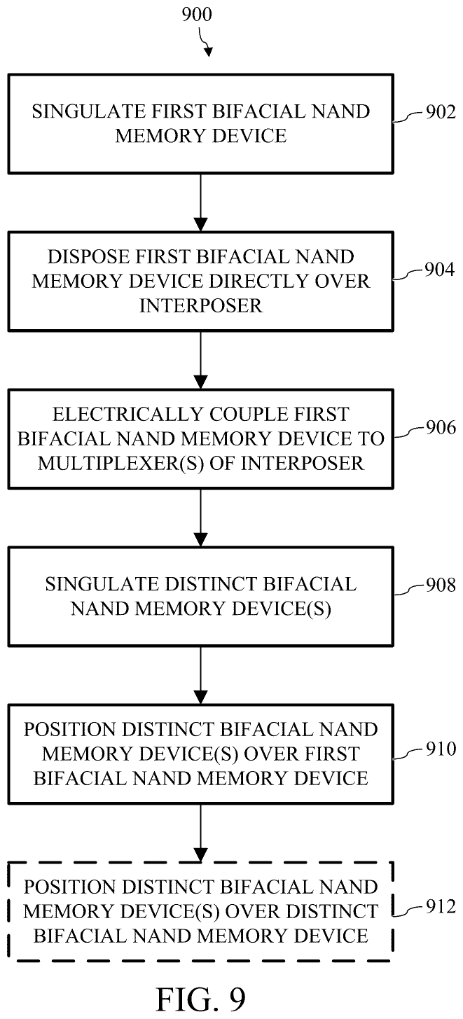

FIG. 9 illustrates another method 900 for fabricating a semiconductor package according to an example. The method 900 and processes therein can be performed to fabricate various semiconductor packages described herein.

In process 902, a first bifacial NAND memory device may be singulated. More specifically, a wafer including a plurality of first bifacial NAND memory device(s) may be singulated, separated, and/or split to form a plurality of single, first bifacial NAND memory devices. Each singulated, first bifacial NAND memory device may include a plurality of TSVs extending therethrough. The first bifacial NAND memory device may be singulated using any suitable technique and/or method.

In process 904 the first bifacial NAND memory device may be disposed directly over an interposer. More specifically, the singulated, first bifacial NAND memory device may be disposed over the interposer such that the first bifacial NAND memory device is positioned directly adjacent to the interposer.

In process 906, the singulated, first bifacial NAND memory device is electrically coupled to the interposer. More specifically, the singulated, first bifacial NAND memory device disposed directly over the interposer may be electrically coupled to the interposer and a plurality of multiplexers (MUX) formed integrally within the interposer. In non-limiting examples, the first bifacial NAND memory device may be electrically coupled to interposer via the TSVs extending through first bifacial NAND memory device and at least one electrical channel extending through the interposer. In non-limiting examples, the first bifacial NAND memory device may be electrically coupled to the interposer, and more specifically the plurality of MUX integrally formed within the interposer, using hybrid wafer-to-wafer (e.g., copper-to-copper) bonding processes, or may be bonded and electrically coupled using solder bumps, balls, pillars, or the like.

In process 908, at least one distinct bifacial NAND memory device may be singulated. More specifically, a wafer including a plurality of distinct bifacial NAND memory device(s) may be singulated, separated, and/or split to form a plurality of single, distinct bifacial NAND memory devices. Each singulated, distinct bifacial NAND memory device may include a plurality of TSVs extending therethrough-similar to first bifacial NAND memory device. The distinct bifacial NAND memory device(s) may be singulated using any suitable technique and/or method.

In process 910, at least one distinct bifacial NAND memory device may be positioned over the first bifacial NAND memory device. More specifically, at least one singulated, distinct bifacial NAND memory device may be positioned, disposed, and/or aligned over the first bifacial NAND memory device. Additionally as discussed herein, each of the at least one bifacial NAND memory devices may be electrically coupled to the first bifacial NAND memory device, and in turn electrically coupled to the plurality of MUX integrally formed within the interposer. The at least one distinct bifacial NAND memory device may be electrically coupled to the interposer via the TSVs extending there through. In non-limiting examples, the distinct bifacial NAND memory device(s) may be electrically coupled to the first bifacial NAND memory device using hybrid wafer-to-wafer (e.g., copper-to-copper) bonding processes, or may be bonded and electrically coupled using solder bumps, balls, pillars, or the like.

In process 912, shown in phantom as optional, at least one distinct bifacial NAND memory device may be positioned over a previously disposed, distinct bifacial NAND memory device. More specifically, at least one singulated, distinct bifacial NAND memory device may be positioned, disposed, and/or aligned over a previously disposed, distinct bifacial NAND memory device (see, process 910). Additionally, and similar to process 910, distinct bifacial NAND memory devices may be electrically coupled to the previously disposed bifacial NAND memory device, and in turn electrically coupled to the plurality of MUX integrally formed within the interposer. The at least one distinct bifacial NAND memory device may be electrically coupled to the interposer via the TSVs extending there through. In non-limiting examples, the distinct bifacial NAND memory device(s) may be electrically coupled to previously disposed bifacial NAND memory device using hybrid wafer-to-wafer (e.g., copper-to-copper) bonding processes, or may be bonded and electrically coupled using solder bumps, balls, pillars, or the like.

It is to be understood that process 912 may be repeated as many times as desired until the fabricated semiconductor package includes a desired number of bifacial NAND memory devices. That is, a predetermined number of bifacial NAND memory devices may be disposed and electrically coupled to one another by repeating process 912 to form the semiconductor package using method 900.

Based on the above, examples of the present disclosure describe a semiconductor package, comprising: an interposer including a plurality of multiplexers (MUX) integrally formed within the interposer; and a plurality of bifacial NAND memory devices disposed over the interposer and electrically coupled to the plurality of MUX, each of the plurality of bifacial NAND memory devices including: a first NAND memory die disposed on a first planar surface; a second NAND memory die disposed on a second planar surface, opposite the first NAND memory die, the second planar surface positioned adjacent the interposer; and a plurality of through silicon vias (TSVs) electrically coupling the first NAND memory die on the first planar surface with: the second NAND memory die on the second planar surface, and the plurality of MUX. In an example, the plurality of bifacial NAND memory devices include: a first bifacial NAND memory device disposed directly over the interposer, wherein the plurality of TSVs of the first bifacial NAND memory device include: a first plurality of TSVs extending through the first NAND memory die of the first bifacial NAND memory device; and a second plurality of TSVs extending through the second NAND memory die of the first bifacial NAND memory device, the second plurality of TSVs electrically coupled to: the first NAND memory die via the first plurality of TSVs, and the plurality of MUX; and at least one distinct bifacial NAND memory device disposed directly over the first bifacial NAND memory device, wherein the plurality of TSVs of the at least one distinct bifacial NAND memory device includes: a first distinct plurality of TSVs extending through the first NAND memory die of the at least one distinct bifacial NAND memory device; and a second distinct plurality of TSVs extending through the second NAND memory die of the at least one distinct bifacial NAND memory device, the second distinct plurality of TSVs electrically coupled to: the first distinct plurality of TSVs of the NAND memory die of the at least one distinct bifacial NAND memory device, and the first plurality of TSVs extending through the first NAND memory die of the first bifacial NAND memory device. In an example, the second plurality of TSVs of the first bifacial NAND memory device is electrically coupled to the plurality of MUX by way of one of: one or more solder bumps, or a hybrid wafer-to-wafer bond. In an example, the second distinct plurality of TSVs of the at least one bifacial NAND memory device is electrically coupled to the first plurality of TSVs extending through the first NAND memory die of the first bifacial NAND memory device by one of: one or more solder bumps, or a hybrid wafer-to-wafer bond. In an example, the semiconductor package also includes a controller electrically coupled to the plurality of MUX and the plurality of bifacial NAND memory devices disposed over the interposer. In an example, the controller is one of: positioned within a recess formed in the interposer, adjacent the plurality of MUX, or disposed on the interposer, opposite the plurality of bifacial NAND memory devices disposed over the interposer. In an example, the controller is disposed over the plurality of bifacial NAND memory device, opposite the interposer. In an example, the semiconductor package also includes a distinct plurality of bifacial NAND memory devices disposed over the interposer, adjacent the plurality of bifacial NAND memory devices, cach of the distinct plurality of bifacial NAND memory device including: a first NAND memory die disposed on a first planar surface; a second NAND memory die disposed on a second planar surface, opposite the first NAND memory die, the second planar surface positioned adjacent the interposer; and a plurality of TSVs electrically coupling the first NAND memory die on the first planar surface with: the second NAND memory die on the second planar surface, and the plurality of MUX; a first redistribution layer positioned between the first NAND memory die of each of the plurality of bifacial NAND memory devices and the first NAND memory die of each of the distinct plurality of bifacial NAND memory devices, the first redistribution layer configured to enable communication between the first NAND memory die of each of the plurality of bifacial NAND memory devices and the first NAND memory die of each of the distinct plurality of bifacial NAND memory devices; and a second redistribution layer positioned between the second NAND memory die of each of the plurality of bifacial NAND memory devices and the second NAND memory die of each of the distinct plurality of bifacial NAND memory devices, the second redistribution layer configured to enable communication between the second NAND memory die of each of the plurality of bifacial NAND memory devices and the second NAND memory die of each of the distinct plurality of bifacial NAND memory devices.

Examples also describe an electronic device, comprising: a printed circuit board (PCB); and at least one semiconductor package positioned on and electrically coupled to the PCB, the at least one semiconductor package including: an interposer disposed directly over and electrically coupled to the PCB, the interposer including a plurality of multiplexers (MUX) integrally formed within the interposer; and a plurality of bifacial NAND memory devices disposed over the interposer and electrically coupled to the plurality of MUX and the PCB, each of the plurality of bifacial NAND memory device including: a first NAND memory die disposed on a first planar surface; a second NAND memory die disposed on a second planar surface, opposite the first NAND memory die, the second planar surface positioned adjacent the interposer; and a plurality of through silicon vias (TSVs) electrically coupling the first NAND memory die on the first planar surface with: the second NAND memory die on the second planar surface, and the plurality of MUX. In an example, the plurality of bifacial NAND memory devices of the at least one semiconductor package include: a first bifacial NAND memory device disposed directly over the interposer, wherein the plurality of TSVs of the first bifacial NAND memory device include: a first plurality of TSVs extending through the first NAND memory die of the first bifacial NAND memory device; and a second plurality of TSVs extending through the second NAND memory die of the first bifacial NAND memory device, the second plurality of TSVs electrically coupled to: the first NAND memory die via the first plurality of TSVs, and the plurality of MUX; and at least one distinct bifacial NAND memory device disposed directly over the first bifacial NAND memory device, wherein the plurality of TSVs of the at least one distinct bifacial NAND memory device includes: a first distinct plurality of TSVs extending through the first NAND memory die of the at least one distinct bifacial NAND memory device; and a second distinct plurality of TSVs extending through the second NAND memory die of the at least one distinct bifacial NAND memory device, the second distinct plurality of TSVs electrically coupled to: the first distinct plurality of TSVs of the NAND memory die of the at least one distinct bifacial NAND memory device, and the first plurality of TSVs extending through the first NAND memory die of the first bifacial NAND memory device. In an example, the second plurality of TSVs of the first bifacial NAND memory device is electrically coupled to the plurality of MUX by way of one of: one or more solder bumps, or a hybrid wafer-to-wafer bond. In an example, the second distinct plurality of TSVs of the at least one bifacial NAND memory device is electrically coupled to the first plurality of TSVs extending through the first NAND memory die of the first bifacial NAND memory device by one of: one or more solder bumps, or a hybrid wafer-to-wafer bond. In an example, the at least one semiconductor package further includes a controller electrically coupled to the plurality of MUX formed integrally within the interposer and the plurality of bifacial NAND memory devices disposed over the interposer. In an example, the controller is one of: positioned within a recess formed in the interposer, adjacent the plurality of MUX, or disposed on the interposer, opposite the plurality of bifacial NAND memory devices disposed over the interposer. In an example, the controller is disposed over the plurality of bifacial NAND memory device, opposite the interposer. In an example, the at least one semiconductor package further includes: a distinct plurality of bifacial NAND memory devices disposed over the interposer, adjacent the plurality of bifacial NAND memory devices, each of the distinct plurality of bifacial NAND memory device including: a first NAND memory die disposed on a first planar surface; a second NAND memory die disposed on a second planar surface, opposite the first NAND memory die, the second planar surface positioned adjacent the interposer; and a plurality of TSVs electrically coupling the first NAND memory die on the first planar surface with: the second NAND memory die on the second planar surface, and the plurality of MUX; a first redistribution layer positioned between the first NAND memory die of each of the plurality of bifacial NAND memory devices and the first NAND memory die of each of the distinct plurality of bifacial NAND memory devices, the first redistribution layer configured to enable communication between the first NAND memory die of each of the plurality of bifacial NAND memory devices and the first NAND memory die of each of the distinct plurality of bifacial NAND memory devices; and a second redistribution layer positioned between the second NAND memory die of each of the plurality of bifacial NAND memory devices and the second NAND memory die of each of the distinct plurality of bifacial NAND memory devices, the second redistribution layer configured to enable communication between the second NAND memory die of each of the plurality of bifacial NAND memory devices and the second NAND memory die of each of the distinct plurality of bifacial NAND memory devices. In an example, the interposer of the at least one semiconductor package is electrically coupled to PCB by one or more solder bumps.

Examples also describe a semiconductor package, comprising: an interposer including a plurality of multiplexers (MUX) integrally formed within the interposer; and a plurality of bifacial NAND memory devices disposed over the interposer, each of the plurality of bifacial NAND memory device including: a first NAND memory die disposed on a first planar surface; a second NAND memory die disposed on a second planar surface, opposite the first NAND memory die, the second planar surface positioned adjacent the interposer; and means for electrically coupling the first NAND memory die on the first planar surface with: the second NAND memory die on the second planar surface, and the plurality of MUX. In an example, the plurality of bifacial NAND memory devices include: a first bifacial NAND memory device disposed directly over the interposer and including: a first means for electrically coupling the first NAND memory die of the first bifacial NAND memory device to the second NAND memory die of the first bifacial NAND memory device; and a second means for electrically coupling the second NAND memory die of the first bifacial NAND memory device to the plurality of MUX; and at least one distinct bifacial NAND memory device disposed directly over the first bifacial NAND memory device, the at least one distinct bifacial NAND memory device including: a first means for electrically coupling the first NAND memory die of the at least one distinct bifacial NAND memory device to the second NAND memory die of the at least one distinct bifacial NAND memory device; and a second means for electrically coupling the second NAND memory die of the at least one distinct bifacial NAND memory device to the first NAND memory die of the first bifacial NAND memory device. In an example, the semiconductor package also includes a controller including means for electrically coupling the controller to the plurality of MUX and the plurality of bifacial NAND memory devices disposed over the interposer.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
an interposer including a plurality of multiplexers (MUX) integrally formed within the interposer; and
a plurality of bifacial NAND memory devices disposed over the interposer and electrically coupled to the plurality of MUX, each of the plurality of bifacial NAND memory devices including:
a first NAND memory die disposed on a first planar surface;
a second NAND memory die disposed on a second planar surface, opposite the first NAND memory die, the second planar surface positioned adjacent the interposer; and
a plurality of through silicon vias (TSVs) electrically coupling the first NAND memory die on the first planar surface with:
the second NAND memory die on the second planar surface, and
the plurality of MUX.

2. The semiconductor package of claim 1, wherein the plurality of bifacial NAND memory devices include:
a first bifacial NAND memory device disposed directly over the interposer, wherein the plurality of TSVs of the first bifacial NAND memory device include:
a first plurality of TSVs extending through the first NAND memory die of the first bifacial NAND memory device; and
a second plurality of TSVs extending through the second NAND memory die of the first bifacial NAND memory device, the second plurality of TSVs electrically coupled to:
the first NAND memory die via the first plurality of TSVs, and
the plurality of MUX; and
at least one distinct bifacial NAND memory device disposed directly over the first bifacial NAND memory device, wherein the plurality of TSVs of the at least one distinct bifacial NAND memory device includes:
a first distinct plurality of TSVs extending through the first NAND memory die of the at least one distinct bifacial NAND memory device; and
a second distinct plurality of TSVs extending through the second NAND memory die of the at least one distinct bifacial NAND memory device, the second distinct plurality of TSVs electrically coupled to:
the first distinct plurality of TSVs of the NAND memory die of the at least one distinct bifacial NAND memory device, and
the first plurality of TSVs extending through the first NAND memory die of the first bifacial NAND memory device.

3. The semiconductor package of claim 2, wherein the second plurality of TSVs of the first bifacial NAND memory device is electrically coupled to the plurality of MUX by way of one of:
one or more solder bumps, or
a hybrid wafer-to-wafer bond.

4. The semiconductor package of claim 2, wherein the second distinct plurality of TSVs of the at least one bifacial NAND memory device is electrically coupled to the first plurality of TSVs extending through the first NAND memory die of the first bifacial NAND memory device by one of:
one or more solder bumps, or
a hybrid wafer-to-wafer bond.

5. The semiconductor package of claim 1, further comprising a controller electrically coupled to the plurality of MUX and the plurality of bifacial NAND memory devices disposed over the interposer.

6. The semiconductor package of claim 5, wherein the controller is one of:
positioned within a recess formed in the interposer, adjacent the plurality of MUX, or
disposed on the interposer, opposite the plurality of bifacial NAND memory devices disposed over the interposer.

7. The semiconductor package of claim 5, wherein the controller is disposed over the plurality of bifacial NAND memory device, opposite the interposer.

8. The semiconductor package of claim 1, further comprising:
a distinct plurality of bifacial NAND memory devices disposed over the interposer, adjacent the plurality of bifacial NAND memory devices, each of the distinct plurality of bifacial NAND memory device including:
a first NAND memory die disposed on a first planar surface;
a second NAND memory die disposed on a second planar surface, opposite the first NAND memory die, the second planar surface positioned adjacent the interposer; and
a plurality of TSVs electrically coupling the first NAND memory die on the first planar surface with:
the second NAND memory die on the second planar surface, and
the plurality of MUX;
a first redistribution layer positioned between the first NAND memory die of each of the plurality of bifacial NAND memory devices and the first NAND memory die of each of the distinct plurality of bifacial NAND memory devices, the first redistribution layer configured to enable communication between the first NAND memory die of each of the plurality of bifacial NAND memory devices and the first NAND memory die of each of the distinct plurality of bifacial NAND memory devices; and
a second redistribution layer positioned between the second NAND memory die of each of the plurality of bifacial NAND memory devices and the second NAND memory die of each of the distinct plurality of bifacial NAND memory devices, the second redistribution layer configured to enable communication between the second NAND memory die of each of the plurality of bifacial NAND memory devices and the second NAND memory die of each of the distinct plurality of bifacial NAND memory devices.

9. An electronic device, comprising:
a printed circuit board (PCB); and
at least one semiconductor package positioned on and electrically coupled to the PCB, the at least one semiconductor package including:
an interposer disposed directly over and electrically coupled to the PCB, the interposer including a plurality of multiplexers (MUX) integrally formed within the interposer; and
a plurality of bifacial NAND memory devices disposed over the interposer and electrically coupled to the plurality of MUX and the PCB, each of the plurality of bifacial NAND memory device including:
a first NAND memory die disposed on a first planar surface;
a second NAND memory die disposed on a second planar surface, opposite the first NAND memory die, the second planar surface positioned adjacent the interposer; and
a plurality of through silicon vias (TSVs) electrically coupling the first NAND memory die on the first planar surface with:
the second NAND memory die on the second planar surface, and
the plurality of MUX.

10. The electronic device of claim 9, wherein the plurality of bifacial NAND memory devices of the at least one semiconductor package include:
a first bifacial NAND memory device disposed directly over the interposer, wherein the plurality of TSVs of the first bifacial NAND memory device include:
a first plurality of TSVs extending through the first NAND memory die of the first bifacial NAND memory device; and
a second plurality of TSVs extending through the second NAND memory die of the first bifacial NAND memory device, the second plurality of TSVs electrically coupled to:
the first NAND memory die via the first plurality of TSVs, and
the plurality of MUX; and
at least one distinct bifacial NAND memory device disposed directly over the first bifacial NAND memory device, wherein the plurality of TSVs of the at least one distinct bifacial NAND memory device includes:
a first distinct plurality of TSVs extending through the first NAND memory die of the at least one distinct bifacial NAND memory device; and
a second distinct plurality of TSVs extending through the second NAND memory die of the at least one distinct bifacial NAND memory device, the second distinct plurality of TSVs electrically coupled to:
the first distinct plurality of TSVs of the NAND memory die of the at least one distinct bifacial NAND memory device, and
the first plurality of TSVs extending through the first NAND memory die of the first bifacial NAND memory device.

11. The electronic device of claim 10, wherein the second plurality of TSVs of the first bifacial NAND memory device is electrically coupled to the plurality of MUX by way of one of:
one or more solder bumps, or
a hybrid wafer-to-wafer bond.

12. The electronic device of claim 10, wherein the second distinct plurality of TSVs of the at least one bifacial NAND memory device is electrically coupled to the first plurality of TSVs extending through the first NAND memory die of the first bifacial NAND memory device by one of:
one or more solder bumps, or
a hybrid wafer-to-wafer bond.

13. The electronic device of claim 9, wherein the at least one semiconductor package further includes a controller electrically coupled to the plurality of MUX formed integrally within the interposer and the plurality of bifacial NAND memory devices disposed over the interposer.

14. The electronic device of claim 13, wherein the controller is one of:
positioned within a recess formed in the interposer, adjacent the plurality of MUX, or disposed on the interposer, opposite the plurality of bifacial NAND memory devices disposed over the interposer.

15. The electronic device of claim 13, wherein the controller is disposed over the plurality of bifacial NAND memory device, opposite the interposer.

16. The electronic device of claim 9, wherein the at least one semiconductor package further includes:
a distinct plurality of bifacial NAND memory devices disposed over the interposer, adjacent the plurality of bifacial NAND memory devices, each of the distinct plurality of bifacial NAND memory device including:
a first NAND memory die disposed on a first planar surface;
a second NAND memory die disposed on a second planar surface, opposite the first NAND memory die, the second planar surface positioned adjacent the interposer; and
a plurality of TSVs electrically coupling the first NAND memory die on the first planar surface with:
the second NAND memory die on the second planar surface, and
the plurality of MUX;
a first redistribution layer positioned between the first NAND memory die of each of the plurality of bifacial NAND memory devices and the first NAND memory die of each of the distinct plurality of bifacial NAND memory devices, the first redistribution layer configured to enable communication between the first NAND memory die of each of the plurality of bifacial NAND memory devices and the first NAND memory die of each of the distinct plurality of bifacial NAND memory devices; and
a second redistribution layer positioned between the second NAND memory die of each of the plurality of bifacial NAND memory devices and the second NAND memory die of each of the distinct plurality of bifacial NAND memory devices, the second redistribution layer configured to enable communication between the second NAND memory die of each of the plurality of bifacial NAND memory devices and the second NAND memory die of each of the distinct plurality of bifacial NAND memory devices.

17. The electronic device of claim 9, wherein the interposer of the at least one semiconductor package is electrically coupled to PCB by one or more solder bumps.

18. A semiconductor package, comprising:
an interposer including a plurality of multiplexers (MUX) integrally formed within the interposer; and
a plurality of bifacial NAND memory devices disposed over the interposer, each of the plurality of bifacial NAND memory device including:
a first NAND memory die disposed on a first planar surface;
a second NAND memory die disposed on a second planar surface, opposite the first NAND memory die, the second planar surface positioned adjacent the interposer; and
means for electrically coupling the first NAND memory die on the first planar surface with:
the second NAND memory die on the second planar surface, and
the plurality of MUX.

19. The semiconductor package of claim 18, wherein the plurality of bifacial NAND memory devices include:
a first bifacial NAND memory device disposed directly over the interposer and including:
a first means for electrically coupling the first NAND memory die of the first bifacial NAND memory device to the second NAND memory die of the first bifacial NAND memory device; and
a second means for electrically coupling the second NAND memory die of the first bifacial NAND memory device to the plurality of MUX; and
at least one distinct bifacial NAND memory device disposed directly over the first bifacial NAND memory device, the at least one distinct bifacial NAND memory device including:
a first means for electrically coupling the first NAND memory die of the at least one distinct bifacial NAND memory device to the second NAND memory die of the at least one distinct bifacial NAND memory device; and
a second means for electrically coupling the second NAND memory die of the at least one distinct bifacial NAND memory device to the first NAND memory die of the first bifacial NAND memory device.

20. The semiconductor package of claim 18, further comprising a controller including means for electrically coupling the controller to the plurality of MUX and the plurality of bifacial NAND memory devices disposed over the interposer.
